(19) United States
(12) Patent Application Publication
(10) Pub. No.: US 2011/0242861 A1
(43) Pub. Date: Oct. 6, 2011

(54) ELECTRONIC DEVICE AND SEMICONDUCTOR DEVICE

(75) Inventors: Kazuhito AYUKAWA, Kanagawa (JP); Nobutoshi KASAI, Kanagawa (JP); Kenya YAMAUCHI, Kanagawa (JP); Takamitsu KANAZAWA, Kanagawa (JP); Daisuke IIJIMA, Kanagawa (JP); Mamoru KITAMURA, Kanagawa (JP); Makoto NAKAMURA, Tokyo (JP)

(73) Assignee: RENESAS ELECTRONICS CORPORATION, Kanagawa (JP)

(21) Appl. No.: 13/043,633

(22) Filed: Mar. 9, 2011

(30) Foreign Application Priority Data
Mar. 31, 2010 (JP) 2010-080225

(51) Int. Cl. H02M 7/08

(52) U.S. Cl. 363/70

(57) ABSTRACT

The present invention provides a method of improving efficiency in a full load region in a PFC power source of an active filter method by controlling a switch circuit of the PFC power source in association with an output power of the PFC power source. A pair of two switches controlling charging/discharging an inductor is provided. A MOSFET switch having a small current capacity is used as one of the switches, and an IGBT switch of a large current capacity is used as the other switch. When an output of a voltage dividing circuit for dividing voltage of an output terminal of the PFC power source is smaller than a threshold voltage, only the MOSFET switch is operated. When the output exceeds a threshold voltage, the IGBT switch is also operated.

### CROSS-REFERENCE TO RELATED APPLICATIONS

The disclosure of Japanese Patent Application No. 2010-80225 filed on Mar. 31, 2010 including the specification, drawings and abstract is incorporated herein by reference in its entirety.

### BACKGROUND OF THE INVENTION

The present invention relates to improvement in characteristics of an electronic device and a semiconductor device used for the electronic device and, more particularly, to a method of improving efficiency of a power source circuit.

At the present time, energy conservation is becoming an important issue.

A power source manufacturer makes all kinds of efforts and expenses to achieve the efficiency specified with a particularly light load (20% of the maximum load) in accordance with standards such as Energy Star 4.0 and 80plus.

At the first stage of a power source of a device requiring an AD-DC power source of 75 W or higher, power factor correction (PFC) for making current flowing in a commercial power source close to sine wave is necessary for suppressing harmonic current.

There are roughly two methods for PFC. One of the methods is a passive filter method of inserting an inductor in an input line of a device to smooth current. The other method is an active filter method of controlling current by using a dedicated PFC controller and a discrete device. In recent years, the active filter method by which miniaturization and reduction in weight can be achieved is the mainstream.

As the active filter method, various methods according to power consumption such as the current continuity mode and the current criticality mode are practically used, and dedicated controllers are provided by manufacturers.

The PFC power source is also required to realize higher efficiency. FIG. 1 is a circuit diagram showing the configuration of a PFC power source of the active filter method examined by the inventors of the present invention.

In a PFC power source of FIG. 1, a PFC controller 1002 controls the on duty of a switch 1001 to maintain an output voltage Vout at a constant voltage on the basis of voltage information VFB and current information ICS. In addition, the PFC controller 1002 makes current in the current information ICS similar to an AC input and performs control of making the flowing current close to the sine wave. As the switch 1001, a semiconductor switch such as MOSFET or IGBT is used.

As a document related to the circuit example, there is Japanese Unexamined Patent Application Publication No. 2009-219329.

### SUMMARY OF THE INVENTION

In the circuit of FIG. 1, a MOSFET or an IGBT is used as the switch 1001.

Since the turn-off of the IGBT is slow, the loss in the switch when the switch is turned off is large. However, the conduction loss is small, so that the efficiency at the time of heavy loading is excellent.

On the other hand, the turn-off of the MOSFET is much faster than that of the IGBT, and the loss at the turn-off is small. On the contrary, the conduction loss is large so that the MOSFET is not suitable for heavy loading, but the efficiency at the time of light loading is excellent.

When the efficiency is increased with a load in a wide range, there is a limit in the case of using one of the switches of the MOSFET and the IGBT.

An object of the present invention is to improve characteristics of an electronic device. Particularly, an object of the invention is to provide a method of improving efficiency in a wide load region in a PFC power source of the active filter method by controlling a switch circuit in the PFC power source in accordance with an output power of the PFC power source.

The above and other objects and novel features of the present invention will become apparent from the description of the specification and the appended drawings.

Outline of representative ones of the inventions disclosed in the application will be briefly described as follows.

In a power source circuit (electronic device) according to a representative embodiment of the invention, an AC full-wave rectifier circuit, an inductor for smoothing, and a diode for rectification are coupled in series and a capacitor for smoothing is grounded between the diode for rectification and an output terminal, and first and second switches for controlling the inductor for smoothing are grounded in parallel.

The power source circuit may further include a voltage dividing circuit for dividing voltage of the output terminal, and the control circuit may control the first and second switches by using an output of the voltage dividing circuit.

In the power source circuit, the control circuit internally may have a threshold voltage, compare the threshold voltage with an output of the voltage dividing circuit, and switch the first and second switches.

In the power source circuit, when the output of the voltage dividing circuit is smaller than the threshold voltage, only the first switch may be operated and, when the output of the voltage dividing circuit is larger than the threshold voltage, the first and second switches may be operated.

In the power source circuit, when the output of the voltage dividing circuit is smaller than the threshold voltage, only the first switch may be operated and, when the output of the voltage dividing circuit is larger than the threshold voltage, only the second switch may be operated.

In another power source circuit according to a representative embodiment of the invention, an AC full-wave rectifier circuit, an inductor for smoothing, and a diode for rectification are coupled in series and a capacitor for smoothing is grounded between the diode for rectification and an output terminal, and first and second switches for controlling the inductor for smoothing are grounded in parallel. A resistor for measurement is further provided between the output terminal and the diode. The control circuit controls the first and second switches by using a potential difference at both ends of the resistor for measurement.

In the power source circuit, the control circuit may have internally a threshold voltage, compare the threshold voltage with the potential difference between both ends of the resistor for measurement, and switch the first and second switches.

In the power source circuit, when the potential difference between both ends of the resistor for measurement is smaller than the threshold voltage, only the first switch may be operated, and when the potential difference between both ends of the resistor for measurement is larger than the threshold voltage, the first and second switches may be operated.

In the power source circuit, when the potential difference between both ends of the resistor for measurement is smaller than the threshold voltage, only the first switch may be operated and, when the potential difference between both ends of the resistor for measurement is larger than the threshold voltage, only the second switch may be operated.

In another power source circuit according to a representative embodiment of the invention, an AC full-wave rectifier circuit, an inductor for smoothing, and a diode for rectification are coupled in series and a capacitor for smoothing is grounded between the diode for rectification and an output terminal, and first and second switches for controlling the inductor for smoothing are grounded in parallel. The first switch is grounded via a first resistor for measurement, the second switch is grounded via a second resistor for measurement, and the control circuit controls the first and second switches by using an addition voltage obtained by adding a voltage at a connection point between the first resistor for measurement and the first switch and a voltage at a connection point between the second resistor for measurement and the second switch.

In the power source circuit, the control circuit may internally have a threshold voltage, compare the threshold voltage and the addition voltage, and switch the first and second switches.

In the power source circuit, when the addition voltage is smaller than the threshold voltage, only the first switch may be operated, and when the addition voltage is larger than the threshold voltage, the first and second switches may be operated.

In the power source circuit, when the addition voltage is smaller than the threshold voltage, only the first switch may be operated, and when the addition voltage is larger than the threshold voltage, only the second switch may be operated.

In another power source circuit according to a representative embodiment of the invention, an AC full-wave rectifier circuit, an inductor for smoothing, and a diode for rectification are coupled in series and a capacitor for smoothing is grounded between the diode for rectification and an output terminal, and first and second switches for controlling the inductor for smoothing are grounded in parallel. A control circuit is further provided, and the control circuit includes a reference voltage circuit for generating a threshold voltage, a voltage is divided by a voltage dividing circuit on the outside of the control circuit, and the control circuit uses an output of the voltage dividing circuit as a threshold.

The power source circuit further has a control circuit. The control circuit includes a reference voltage circuit for generating a threshold voltage, an output of the reference voltage circuit is divided by first and second voltage dividing circuits on the outside of the control circuit, and the control circuit may use an output of the first voltage dividing circuit as a first voltage threshold and use an output of the second voltage dividing circuit as a second voltage threshold.

In the power source circuit, the control circuit has an AC detection circuit and a change-over switch, the change-over switch can switch the first and second voltage thresholds, and the AC detection circuit may switch the change-over switch using an output of the AC full-wave rectifier circuit as a reference.

In those power source circuits, the first switch may be a MOSFET switch, and the second switch may be an IGBT switch.

In those power source circuits, current capacity of the first switch may be smaller than that of the second switch.

By using the power source circuit (electronic device) of the present invention, the characteristics of a switch of small current capacity (for example, MOSFET) and a switch of large current capacity (for example, IGBT) are utilized and high efficiency can be realized in a load region of a wide range.

### BRIEF DESCRIPTION OF THE DRAWINGS

FIG. 1 is a circuit diagram showing the configuration of a conventional PFC power source of an active filter method;

FIG. 2 is a circuit diagram showing the configuration of a PFC power source of the active filter method according to a first embodiment of the present invention;

FIG. 3 is a timing chart of the operation of a PFC controller;

FIG. 4 is a circuit diagram showing the configuration of another driver selection circuit according to the first embodiment of the present invention;

FIG. 5 is a timing chart of the operation of a PFC controller when the driver selection circuit of FIG. 4 is employed;

FIG. 6 is a circuit diagram showing the configuration of a PFC power source of the active filter method according to a second embodiment of the invention;

FIG. 7 is a circuit diagram showing the configuration of a PFC power source of the active filter method according to a third embodiment of the invention;

FIG. 8 is a timing chart of the operation of a PFC controller when the driver selection circuit of FIG. 7 is employed;

FIG. 9 is a circuit diagram showing the configuration of a PFC power source of the active filter method according to a fourth embodiment of the invention;

FIG. 10 is a circuit diagram showing the configuration of a PFC power source of the active filter method according to a fifth embodiment of the invention;

FIG. 11 is a circuit diagram showing the configuration of a PFC power source of the active filter method according to a sixth embodiment of the invention;

FIG. 12 is a conceptual diagram showing allocation of packaging of circuits related to the present invention;

FIG. 13 is a conceptual diagram showing another allocation of packaging of circuits related to the present invention;

FIG. 14 is a conceptual diagram showing another allocation of packaging of circuits related to the present invention;

FIG. 15 is a conceptual diagram showing another allocation of packaging of circuits related to the present invention;

FIG. 16 is a conceptual diagram showing another allocation of packaging of circuits related to the present invention;

FIG. 17 is a conceptual diagram showing another allocation of packaging of circuits related to the present invention;

FIG. 18 is a partial cross section of a semiconductor chip in which an IGBT is formed;

FIG. 19 is a cross section of a main part of a semiconductor chip 4PH in which a MOSFET is formed;

FIGS. 20A to 20C are diagrams showing a package structure of a part corresponding to SW_PK;

FIG. 21 is a diagram showing the internal structure of FIGS. 20A to 20C;

FIG. 22 is a diagram showing an equivalent circuit of FIG. 21;

FIG. 23 is a diagram showing an equivalent circuit of FIG. 24; and

FIG. 24 is a diagram showing an internal structure of another package of a part corresponding to SW_PK.

### DETAILED DESCRIPTION OF THE PREFERRED EMBODIMENTS

In the following embodiments, the invention will be described by being divided to a plurality of sections or embodiments as necessary for convenience. However, unless otherwise explicitly described, the divided sections or embodiments are not unrelated but one is modification, details, supplementary explanation, or the like of a part or all of another. In the case of referring to the number of elements (including the number of pieces, a numerical value, quantity, range, and the like) in the following embodiments, except for the case when clearly specified or the case a specific number is clearly limited in principle, the invention is not limited to the number. A number equal to or larger/smaller than the specific number may be used.

Further, in the following embodiments, except for the case where the element is specifically clearly mentioned and considered to be clearly necessary in principle, obviously, the element is not always essential. Circuit elements configuring each of function blocks of the embodiments are, although not limited, formed on a semiconductor substrate made of single crystal silicon or the like by an integrated circuit technique of a Complementary MOS transistor (CMOS) and the like. In the embodiments, in the case of describing a Metal Oxide Semiconductor Field Effect Transistor (MOSFET), a nonoxide film is not excluded as the gate insulating film.

In the following, embodiments of the present invention will be described by using the drawings.

### First Embodiment

### Configuration of PFC Power Source

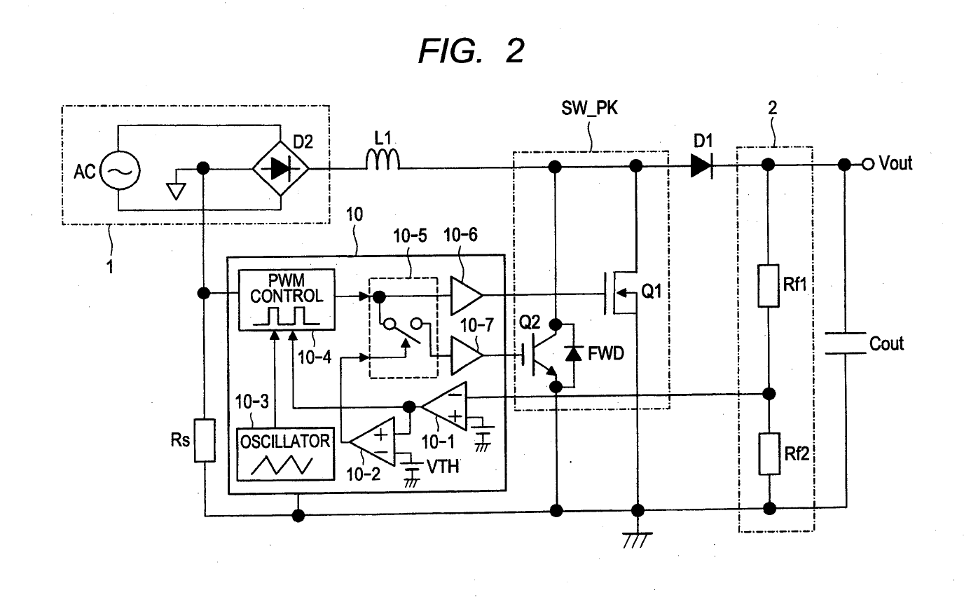

FIG. 2 is a circuit diagram showing the configuration of a PFC power source of the active filter method according to a first embodiment of the present invention.

The PFC power source of the active filter method includes a power source unit 1, an inductor L1, a diode D1, a voltage dividing circuit 2, a capacitor Cout, and a current detection resistor Rs and, in addition, a PFC controller 10, a MOSFET switch Q1, and an IGBT switch Q2.

The power source unit 1 is a circuit for full-wave rectifying an AC power source AC.

The inductor L1 is a coil which generates back electromotive force to stabilize (to smooth) output voltage Vout when the MOSFET switch Q1 or the IGBT switch Q2 is turned off.

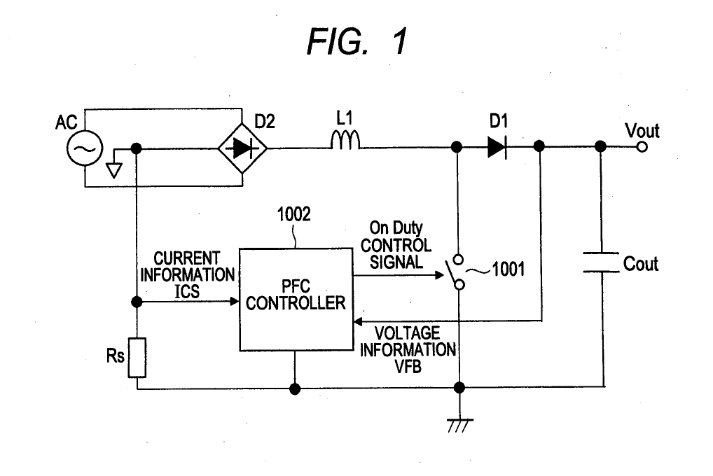

The inductor L1 needs a switch for switching between grounding to charge energy and discharging of energy charged in the inductor L1. This corresponds to a switch 1001 in FIG. 1 and corresponds to the MOSFET switch Q1 and the IGBT switch Q2 in the embodiment.

The diode D1 is a passive element for rectification to control the flow of current in one direction.

The capacitor Cout is a grounded capacitor for smoothing. The voltage dividing circuit 2 is made by resistors Rf1 and Rf2. The voltage dividing circuit 2 divides the potential difference between the voltage of the output terminal and the ground level and outputs the resultant as voltage information VFB to the PFC controller 10.

The current detection register Rs is a short-circuit-preventing grounding resistor for detecting an output of the power source unit 1 (current information output ICS).

The PFC controller 10 is a control circuit for switching the IGBT switch Q2 using the voltage information VFB and the current information output ICS as inputs. The details of the operation will be described later.

The MOSFET switch Q1 is a MOSFET transistor, and the IGBT switch Q2 is an insulated gate bipolar transistor. To the IGBT switch Q2, a free wheel diode FWD is coupled. Since those devices are common ones, they will not be described.

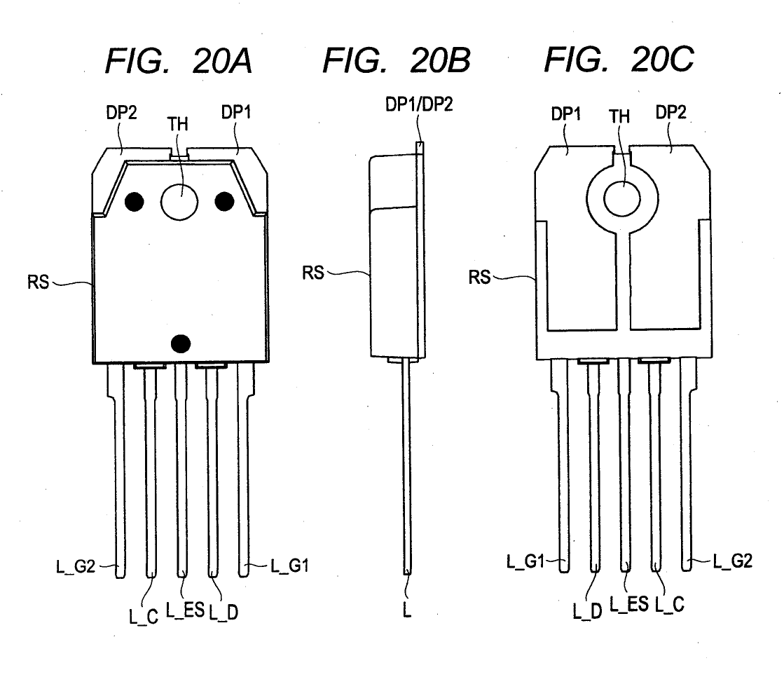

The MOSFET switch Q1 and the IGBT switch Q2 can be enclosed in one package. FIGS. 20A to 20C are diagrams showing how to package a portion corresponding to SW_PW in FIG. 2.

FIG. 20A is a diagram showing names of terminals of SW_PK. FIG. 20B is a diagram showing pin arrangement of the terminals when the switches are actually packaged. The two switches can be mounted in a single package.

When the switches are turned on, energy is accumulated in the inductor L1. When the switches are turned off, the charges are discharged and output to the capacitor Cout, and the output voltage Vout is output from the output terminal.

The current capacity (input capacity) of the MOSFET is generally small, and the IGBT has a characteristic of large current capacity (input capacity). This characteristic is used in the present invention.

Next, the operation of the PFC controller 10 will be described.

The PFC controller 10 has therein an error amplifier 10-1, a load detector 10-2, an oscillator 10-3, a PWM control circuit 10-4, a driver selection circuit 10-5, a MOSFET driver 10-6, and an IGBT driver 10-7.

The error amplifier 10-1 is an operational amplifier for amplifying the voltage information VFB supplied from the voltage dividing circuit 2 to a voltage which can be used by the load detector 10-2 and the PWM control circuit 10-4.

The load detector 10-2 is a comparator for comparing the output of the error amplifier 10-1 with a threshold voltage Vth and outputting a signal to the driver selection circuit 10-5.

The oscillator 10-3 is an internal oscillator for generating a triangular wave.

The PWM control circuit 10-4 is a control circuit for comparing the current information output ICS from the power source unit 1 with the triangular wave output from the oscillator 10-3 to determine “on duty” of the MOSFET driver 10-6 and the IGBT driver 10-7.

The driver selection circuit 10-5 is a selection circuit for determining the presence/absence of operation of the IGBT driver 10-7 on the basis of an output of the load detector 10-2.

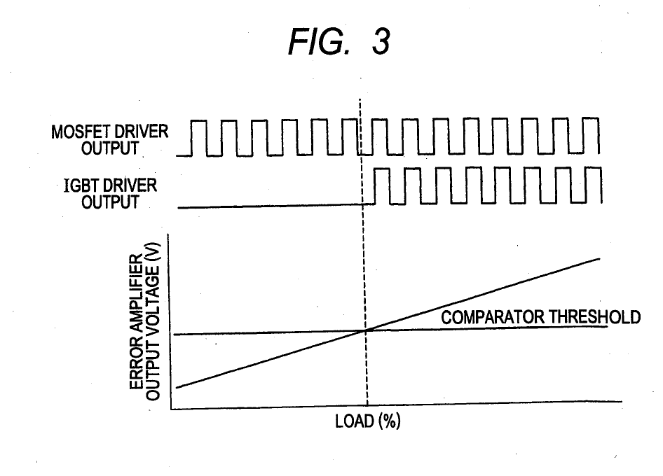

FIG. 3 is a timing chart of the operation of the PFC controller 10.

In the invention, the load level is determined on the basis of the output level of the error amplifier 10-1.

In the case where the output of the error amplifier 10-1 is equal to or less than the predetermined threshold (threshold voltage Vth in FIG. 2), the operation of the IGBT driver 10-7 is stopped by the driver selection circuit 10-5. On the other hand, after lapse of predetermined time, when the level of the load increases and exceeds the threshold, the IGBT driver 10-7 is also operated.

With such a configuration, high efficiency can be realized in a wide load region.

In the above, the MOSFET switch Q1 and the IGBT switch Q2 were used. However, a small-capacity MOSFET can be used in place of the MOSFET switch Q1, and a large-capacity MOSFET can be used in place of the IGBT switch Q2. At least the relative relation that the current capacity of the switch used in place of the MOSFET switch Q1 is smaller than that of the switch used in place of the IGBT switch Q2 has to be satisfied.

In the embodiment, the driver selection circuit 10-5 switches the on/off state of the IGBT switch Q2. It is also possible to switch to use between the MOSFET switch Q1 and the IGBT switch Q2.

### Configuration of Another Driver Selection Circuit

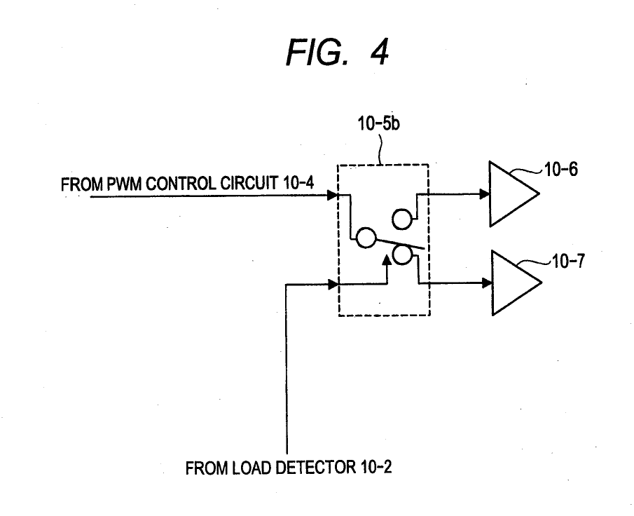

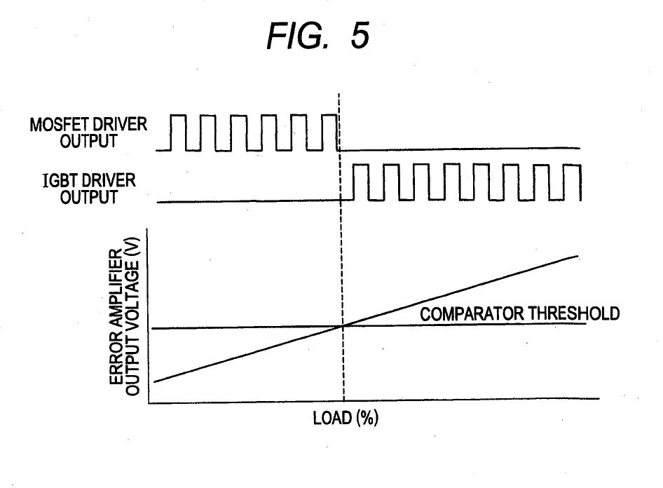

FIG. 4 is a circuit diagram showing the configuration of another driver selection circuit 10-5b according to the first embodiment of the present invention. FIG. 5 is a timing chart of the operation of the PFC controller 10 when the driver selection circuit 10-5b of FIG. 4 is employed. As understood from FIG. 5, in the case of using the driver selection circuit 10-5b of FIG. 4, the operation is switched from the MOSFET switch Q1 to the IGBT switch Q2 when the output of the error amplifier 10-1 exceeds the threshold voltage Vth. There is room for employment of such a configuration.

### IGBT Structure

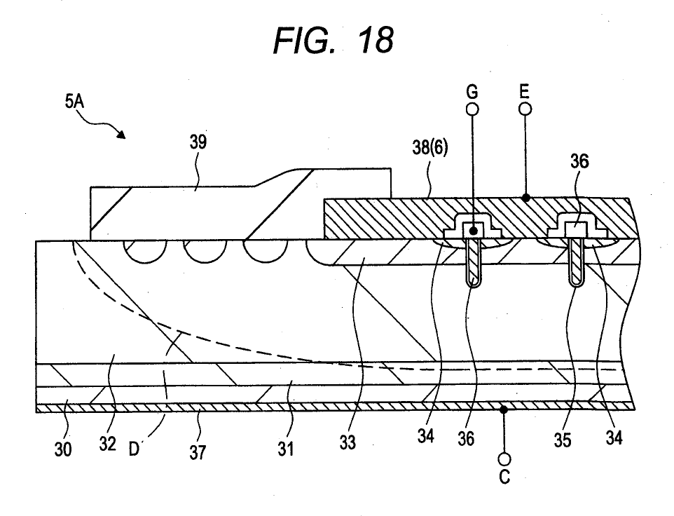

FIG. 18 is a partial cross section of a semiconductor chip in which the IGBT is formed.

On a p+ type silicon substrate 30, an n⁺ type buffer layer 31 and an n⁻ type epitaxial layer 32 are formed. On the surface of the n⁻ type epitaxial layer 32, a p⁺ type diffusion layer 33 and an n⁺ type diffusion layer 34 are formed. In a part of the n⁺ type diffusion layer 34, a trench penetrating the n⁺ type diffusion layer 34 and the p⁺ type diffusion layer 33 and reaching the n⁻ type epitaxial layer 32 is formed. In the trench, a gate insulating film 35 as a silicon oxide film and a gate electrode 36 made by a polysilicon film are formed.

The p+ type silicon substrate 30, the n⁺ type buffer layer 31, the n⁻ type epitaxial layer 32, and the p⁺ type diffusion layer 33 configure a pnp transistor part in the IGBT, and the p⁺ type diffusion layer 33, the n⁺ type diffusion layer 34, the gate insulating film 35, and the gate electrode 36 configure a MOSFET part in the IGBT. On the rear face of the p⁺ type silicon substrate 30, a collector electrode 37 is formed. On the p⁺ type diffusion layer 33 and the n+ type diffusion layer 34, an emitter electrode 38 is formed.

On the emitter electrode 38, a surface protection film 39 covering the outermost surface of the p⁺ type silicon substrate 30 is formed. The emitter electrode 38 is made by an Al alloy film, and the surface protection film 39 is a polyimide resin film. A region which is not covered with the surface protection film 39, in the emitter electrode 38, that is, the region exposed from the surface of a semiconductor chip 5A serves as an emitter pad 6. Although not shown, to the gate electrode 36, a gate extraction electrode made by the Al alloy film which is the same layer as that of the emitter electrode 38 is coupled. In the gate extraction electrode, a region which is not covered with the surface protection film 39, that is, the region exposed from the surface of the semiconductor chip 5A serves as a gate pad.

### MOSFET Structure

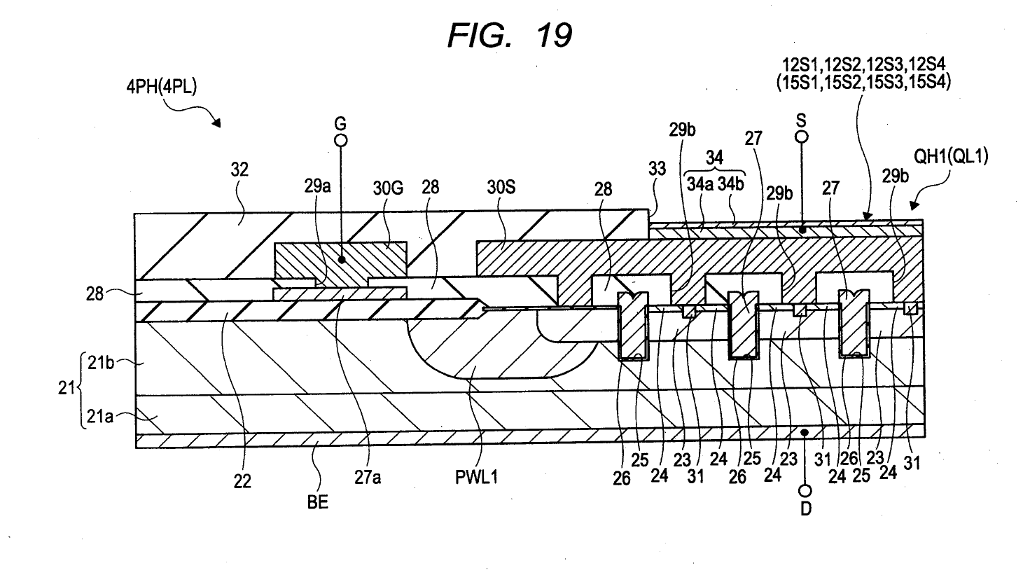

FIG. 19 is a cross section of a main part of the semiconductor chip in which the MOSFET is formed.

The MOSFET is formed on the main face of a semiconductor substrate (hereinbelow, simply called substrate) 21. As shown in FIG. 19, the substrate 21 is a so-called epitaxial wafer having a substrate body (semiconductor substrate, semiconductor wafer) 21a made of, for example, n⁺ type single crystal silicon in which arsenic (As) is introduced and an epitaxial layer (semiconductor layer) 21b made of, for example, n⁻ type silicon single crystal, formed on the main face of the substrate body 21a.

On the main face of the epitaxial layer 21b, a field insulating film (device isolation region) 22 is formed. A plurality of unit transistor cells configuring a MOSFET are formed in an active region surrounded by the field insulating film 22 and a p-type well PWL1 as an underlayer of the field insulating film 22. The MOSFET is formed by coupling the plurality of unit transistor cells in parallel. Each unit transistor cell is formed by, for example, a MOSFET of an n-channel type having a trench gate structure.

The substrate body 21a and the epitaxial layer 21b have the function of the drain region of the unit transistor cell. A backside electrode (backside drain electrode, drain electrode) BE for a drain electrode is formed on the back side of the substrate 21 (semiconductor chip 4PH).

A p-type semiconductor region 23 formed in the epitaxial layer 21b has the function of a channel formation region of the unit transistor cell. Further, an n⁺ type semiconductor region 24 formed on the p-type semiconductor region 23 has the function of a source region of the unit transistor cell. Therefore, the semiconductor region 24 is a semiconductor region for the source.

In the substrate 21, a trench 25 extending from the main face of the substrate 21 to the thickness direction of the substrate 21 is formed. The trench 25 is formed so as to penetrate the n⁺ type semiconductor region 24 and the p type semiconductor region 23 from the top face of the n⁺ type semiconductor region 24 and ends in the epitaxial layer 21b below the p type semiconductor region 23. A gate insulating film 26 made of, for example, silicon oxide is formed on the bottom face and side faces of the trench 25. In the trench 25, a gate electrode 27 is buried via the gate insulating film 26. The gate electrode 27 is formed by, for example, a polysilicon film in which an n-type impurity (for example, phosphorus) is added. The gate electrode 27 has the function of the gate electrode of the unit transistor cell. Also in a part on the field insulating film 22, a wiring part 27a for gate extraction made by the same conductive film as that of the gate electrode 27 is formed. The gate electrode 27 and the wiring part 27a for gate extraction are integrally formed and electrically coupled to each other. In a region which is not shown in the cross section of FIG. 19, the gate electrode 27 and the wiring part 27a for gate extraction are integrally coupled. The wiring part 27a for gate extraction is electrically coupled to a gate wire 30G via a contact hole 29a formed in an insulating film 28 covering the wiring part 27a.

On the other hand, a source wire 30S is electrically coupled to the n⁺ type semiconductor region 24 for the source via a contact hole 29b formed in the insulating film 28. The source wire 30S is electrically coupled to the p⁺ type semiconductor region 31 formed between the n⁺ type semiconductor regions 24 on the p type semiconductor region 23 and is electrically coupled to the p type semiconductor region 23 for formation of the channel via the p⁺ type semiconductor region 31. The gate wire 30G and the source wire 30S are formed by forming a metal film such as an aluminum film so as to bury the contact holes 29a and 29b and patterning the metal film.

The gate wire 30G and the source wire 30S are covered with a protection film (insulating film) 32 made of polyimide resin or the like. The protection film 32 is a film (insulating film) as the uppermost layer of the semiconductor chip 4PH.

In a part of the protection film 32, an opening 33 from which a part of the gate wire 30G and the source wire 30S as the underlayer are exposed is formed. The gate wire 30G part exposed from the opening 33 is the pad 12G for the gate electrode, and the source wire 30S part exposed from the opening 33 is the pads 12S1, 12S2, 12S3, and 12S4 for the source electrode.

A metal layer 34 is formed on the surface of the pads 12G, 12S1, 12S2, 12S3, and 12S4 (that is, on the gate wire 30G part and the source wire 30S part exposed at the bottom of the opening 33).

### Second Embodiment

Next, a second embodiment of the present invention will be described.

The first embodiment is an embodiment adapted to the current continuity mode. On the other hand, the second embodiment is adapted to a current criticality mode.

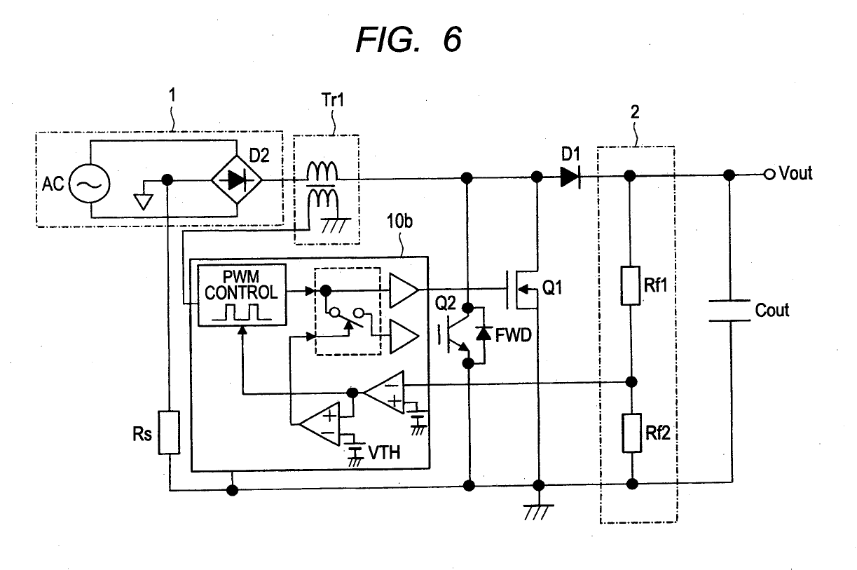

FIG. 6 is a circuit diagram showing the configuration of a PFC power source of the active filter method according to the second embodiment of the invention. In the embodiment, a transformer Tr1 is used in place of the inductor L1, and a PFC controller 10b is used in place of the PFC controller 10.

In the embodiment, zero current detection is performed by a secondary winding of the transformer Tr1. On the basis of an output of the transformer Tr1, the PFC controller 10b operates.

The basic configuration of the PFC controller 10b is similar to that of the PFC controller 10 of the first embodiment but the oscillator 10-3 is not provided. The PFC controller 10b in the current criticality mode oscillates using the current 0 of the transformer Tr1 as a trigger.

Also with such a configuration, the waveform of FIG. 3 can be obtained like the first embodiment.

By applying the driver selection circuit 10-5b of FIG. 4 related to the second embodiment, only the MOSFET Q1 can be used when the load is light, and only the IGBT switch Q2 can be used when the load is heavy.

### Third Embodiment

Next, a third embodiment of the present invention will be described.

In the first and second embodiments, the level of the load is detected by the voltage output from the voltage dividing circuit 2.

In contrast, in the third embodiment, the driver selection circuit 10-5 is operated by using output current.

FIG. 7 is a circuit diagram showing the configuration of a PFC power source of the active filter method according to a third embodiment of the invention.

In the PFC power source, a current measurement resistor R1 is inserted just before the output terminal. The third embodiment is characterized in the point that voltages before and after the current measurement resistor R1 are input to a load detection circuit 10-2c.

The current measurement resistor R1 is a resistor for measuring current flowing in the output terminal by using Ohm's law (voltage V=resistance value R×current I).

The voltages before and after the current measurement resistor R1 are input to the load detection circuit 10-2c. The load detection circuit 10-2c is configured by operational amplifiers in two stages.

The operational amplifier in the input first stage from the current measurement resistor R1, in the load detection circuit 10-2c amplifies the potential difference between the voltages before and after the current measurement resistor R1 for the reason that when the voltage of the current measurement resistor R1 can be determined, the current value is also obtained from the Ohm's law.

The operational amplifier in the latter stage in the load detection circuit 10-2c amplifies the difference between the potential difference amplified by the operational amplifier in the input first stage and the threshold voltage Vth. The threshold voltage Vth is not always equal to the threshold voltage Vth in the first embodiment. The threshold voltage Vth is according to design matters.

As described above, the load detection circuit operates using the voltages before and after the current measurement resistor R1. Therefore, the output from the error amplifier 10-1 is supplied only to the PWM control circuit but is not supplied to the load detection circuit 10-2c.

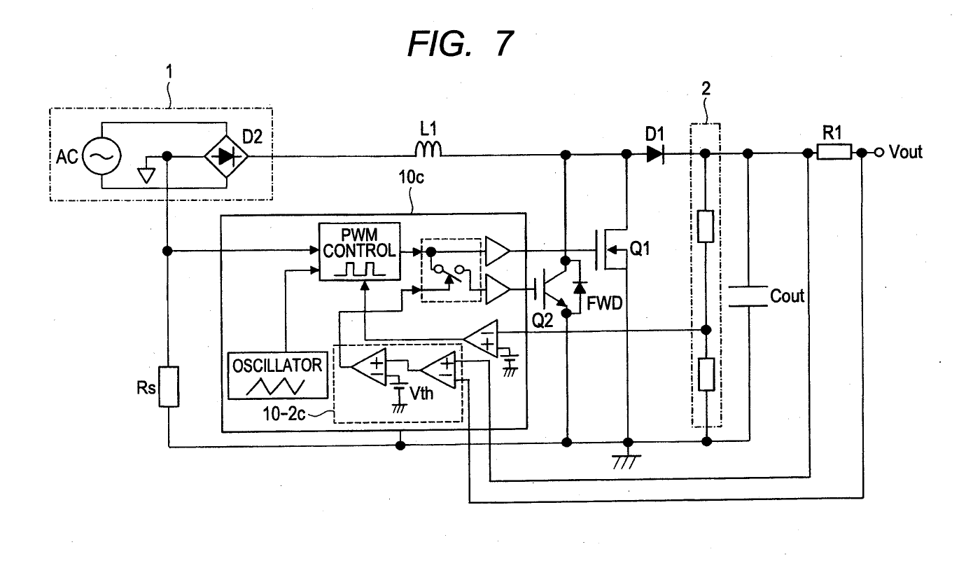

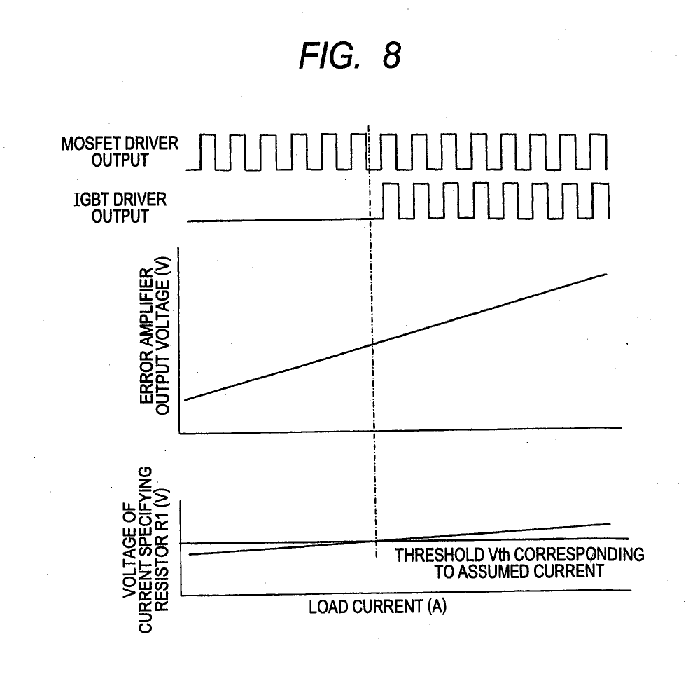

FIG. 8 is a timing chart of the operation of the PFC controller 10 when the driver selection circuit 10-5 of FIG. 7 is employed.

FIG. 8 is basically similar to FIG. 3. The signal which is supplied to the driver selection circuit 10-5 is an output of the PWM control circuit 10-4 and an output of the load detection circuit 10-2c. Therefore, FIG. 8 is characterized by the point that the threshold is set for the voltage value of the current measurement resistor R1.

Also with such a configuration, an effect similar to that of the first embodiment can be obtained.

The method of switching the switch by using the voltage value of the current measurement resistor R1 can also be applied to the circuit of FIG. 4 and the circuit of FIG. 5.

### Fourth Embodiment

Next, a fourth embodiment of the present invention will be described.

The IGBT switch Q2 (and the MOSFET switch Q1) is switched by referring to the voltage level of the output terminal in the first and second embodiments and by referring to the current level of the output terminal in the third embodiment.

The fourth embodiment is characterized in that, by monitoring currents flowing in the switches (the MOSFET switch Q1 and the IGBT switch Q2), the state of the load of each of the switches is determined.

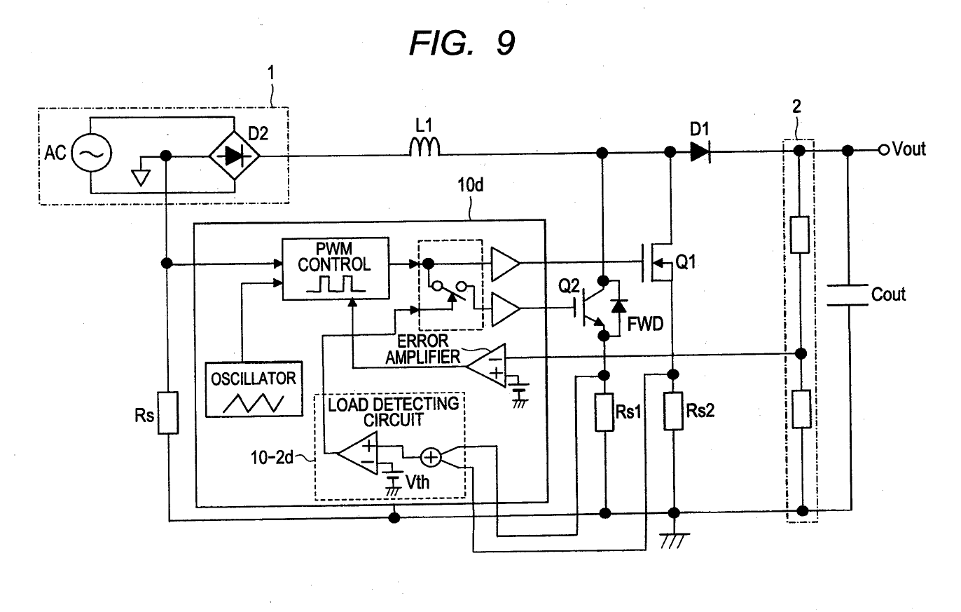

FIG. 9 is a circuit diagram showing the configuration of the PFC power source of the active filter method according to the fourth embodiment of the invention.

The fourth embodiment is characterized by, in addition to insertion of the two resistors for detecting the currents flowing in the switches, a load detection circuit in a PFC controller 10d.

In the embodiment, a resistor Rs1 is inserted on the ground side of the MOSFET switch Q1, and a resistor Rs2 is inserted on the ground side of the IGBT switch Q2.

In this case, to obtain the correspondence between the voltage and current processed according to the Ohm's law, the process is more easily performed when the values of the resistors Rs1 and Rs2 are equal. However, in the case of giving a hysteresis to the load, it is considered to make the values of the resistors Rs1 and Rs2 vary.

The voltages of the resistors Rs1 and Rs2 are added by an adder in the load detection circuit 10-2d. The addition result is compared with the threshold voltage Vth by the operational amplifier in the load detection circuit 10-2d. From the Ohm's law, when the resistance value and the voltage are determined, current is determined. Therefore, it is sufficient to assume target current at a designing stage and determine the threshold voltage Vth corresponding to the target current.

Also by switching the driver selection circuit 10-5 by using the currents flowing in the switch elements as described above, an effect similar to that of the first embodiment can be obtained.

The fourth embodiment can also be applied to a power source circuit employing the circuits of FIGS. 4 and 5.

### Fifth Embodiment

Next, a fifth embodiment of the present invention will be described.

In the first to fourth embodiments, the threshold voltages of the load detector 10-2 and the load detection circuits 10-2c and 10-2d are input to the load detector 10-2 and the like in the PFC controller.

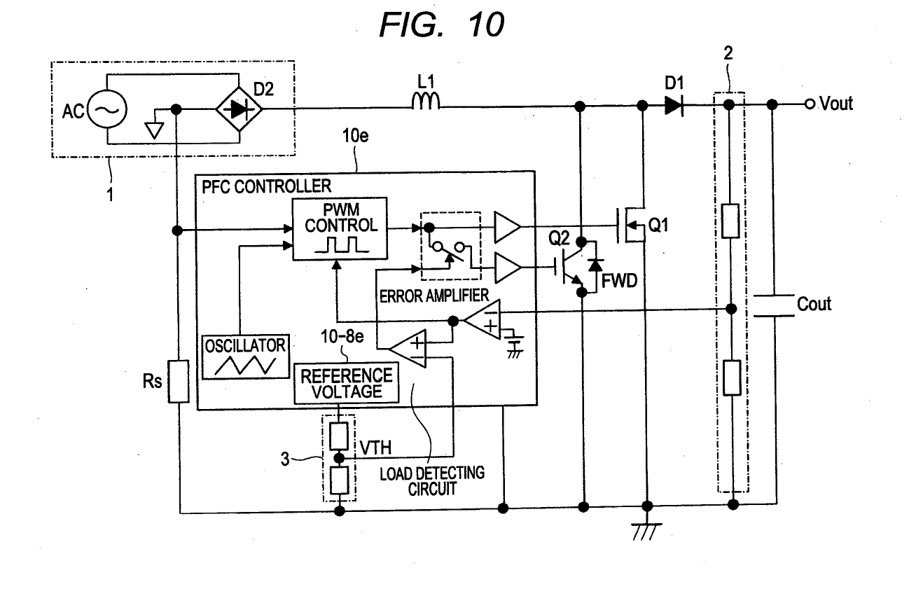

FIG. 10 is a circuit diagram showing the configuration of a PFC power source of the active filter method according to the fifth embodiment of the invention. The circuit uses, as the base, the PFC power source of the active filter method of FIG. 2.

The PFC power source of the active filter method of the embodiment has a voltage dividing circuit 3. A reference voltage circuit 10-8e is included in a PFC controller 10e.

The reference voltage circuit 10-8e is a voltage generating circuit provided for the PFC controller 10e. In the first to fourth embodiments, the reference voltage is input to an internal load detector or the like. In contrast, in the fifth embodiment, the output of the reference voltage circuit 10-8e is once output to the outside of the PFC controller 10e.

The output of the reference voltage circuit 10-8e is divided on the outside of the PFC controller 10e and a desired voltage is generated and returned to the PFC controller 10e. The voltage division is performed by the voltage dividing circuit 3.

With such a configuration, the MOSFET switch Q1 and the IGBT switch Q2 can be controlled with the optimum load. Tuning can be performed while checking the operation of an actual product during manufacture of products, and settings can be adjusted before quantity production.

FIG. 10 is based on FIG. 2 related to the first embodiment. It can also be applied to the second to fourth embodiments.

By using variable resistors as any one of or both of resistors configuring the voltage dividing circuit 3, the setting work can be made easier.

### Sixth Embodiment

Next, a sixth embodiment of the invention will be described.

The sixth embodiment of the invention can provide a power source which is adapted to both the AC 100V system and the AC 200V system by switching the threshold voltage.

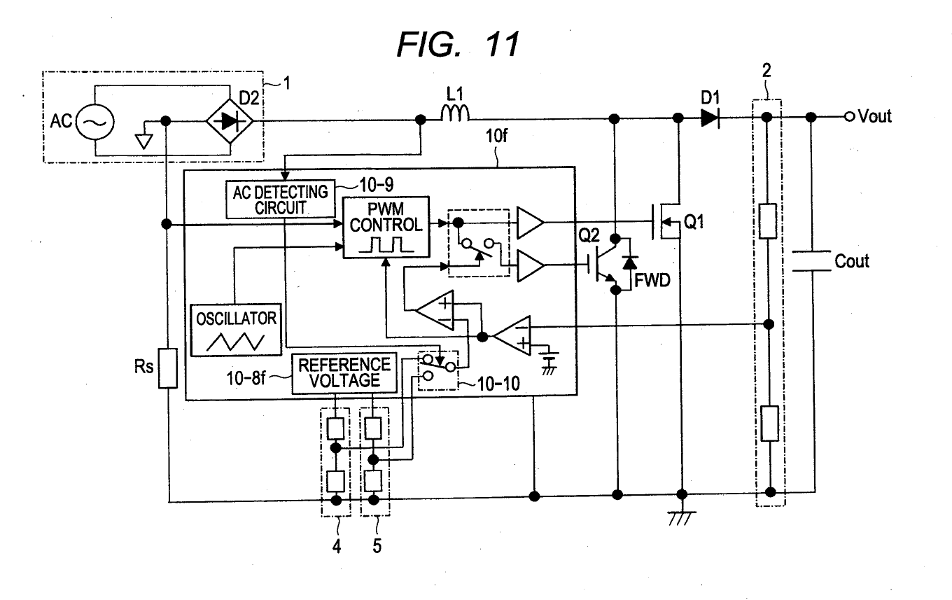

FIG. 11 is a circuit diagram showing the configuration of a PFC power source of the active filter method according to the sixth embodiment of the invention. The circuit uses, as the base, the PFC power source of the active filter method of FIG. 2.

In the embodiment, a PFC controller 10f has therein an AC detection circuit 10-9, a reference voltage circuit 10-8f, and a change-over switch 10-10. It also includes voltage dividing circuits 4 and 5 of two systems.

The AC detection circuit 10-9 is a voltage detection circuit for detecting a voltage output from the power source unit 1. The AC detection circuit 10-9 switches the change-over switch 10-10 in accordance with a result of detection.

The reference voltage circuit 10-8f is a circuit which is basically the same as the reference voltage circuit 10-8e of the fifth embodiment except that outputs of two systems exist.

The voltage dividing circuits 4 and 5 are voltage dividing circuits for supplying the reference voltage to the load detector 10-2 via the change-over switch 10-10.

In the diagram, the reference voltage circuit 10-8f supplies outputs of the two systems to the voltage dividing circuits 4 and 5. Alternatively, an output of one system may be supplied like the reference voltage circuit 10-8e. In this case, by changing the setting of the voltage dividing circuits 4 and 5, the voltage dividing circuits 4 and 5 supply different voltages to the change-over switch 10-10.

With such a configuration, according to the output voltage of the power source unit 1, the threshold voltage can be switched. Consequently, the voltage can be properly switched between the AC 200V system and the AC 100V system.

### Seventh Embodiment

Next, a seventh embodiment of the invention will be described.

In the foregoing first to sixth embodiments, how to package the components has not been described.

In the seventh embodiment, how to package the components will be described.

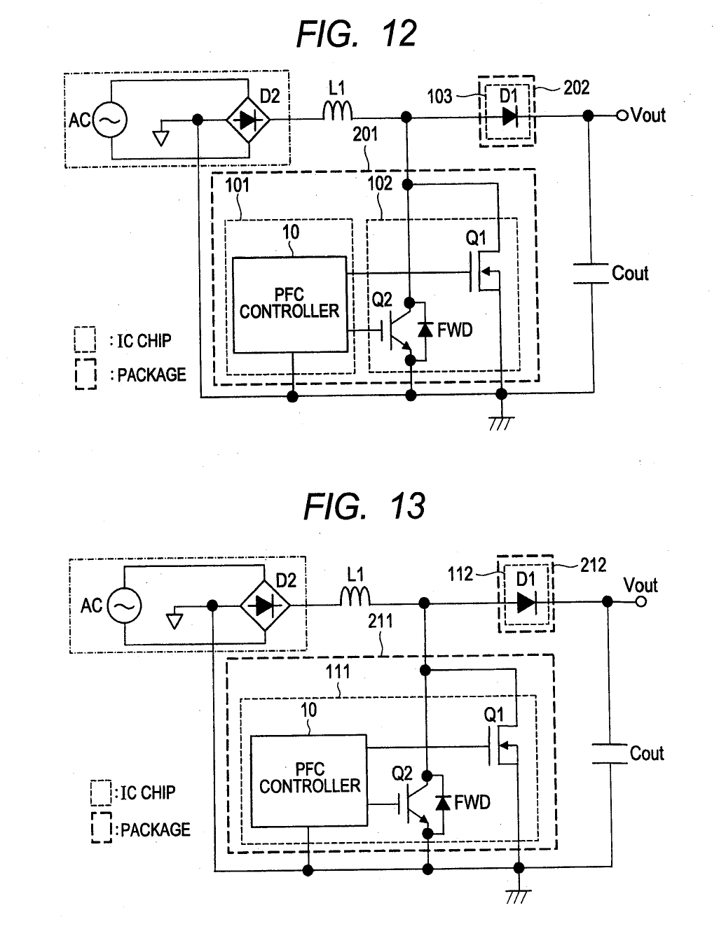

FIG. 12 is a conceptual diagram showing allocation of packaging of circuits related to the present invention. Although the diagram shows the circuits related to the first embodiment of the invention, it can be similarly applied to the other second to sixth embodiments.

In the diagram, the PFC controller 10 is mounted on a first IC chip 101, and the MOSFET switch Q1 and the IGBT switch Q2 are mounted on a second IC chip 102. The first and second IC chips 101 and 102 are mounted on a first package 201.

The diode D1 is mounted on another third IC chip 103. The third IC chip 103 is singularly mounted on a second package 202.

FIG. 13 is a conceptual diagram showing allocation of another packaging of circuits related to the invention.

In the diagram, the PFC controller 10, the MOSFET switch Q1 and the IGBT switch Q2 are mounted on a first IC chip 111. The diode D1 is mounted on another second IC chip 112. The first IC chip 111 is mounted on a first package 211, and the second IC chip 112 is mounted on a second package 212.

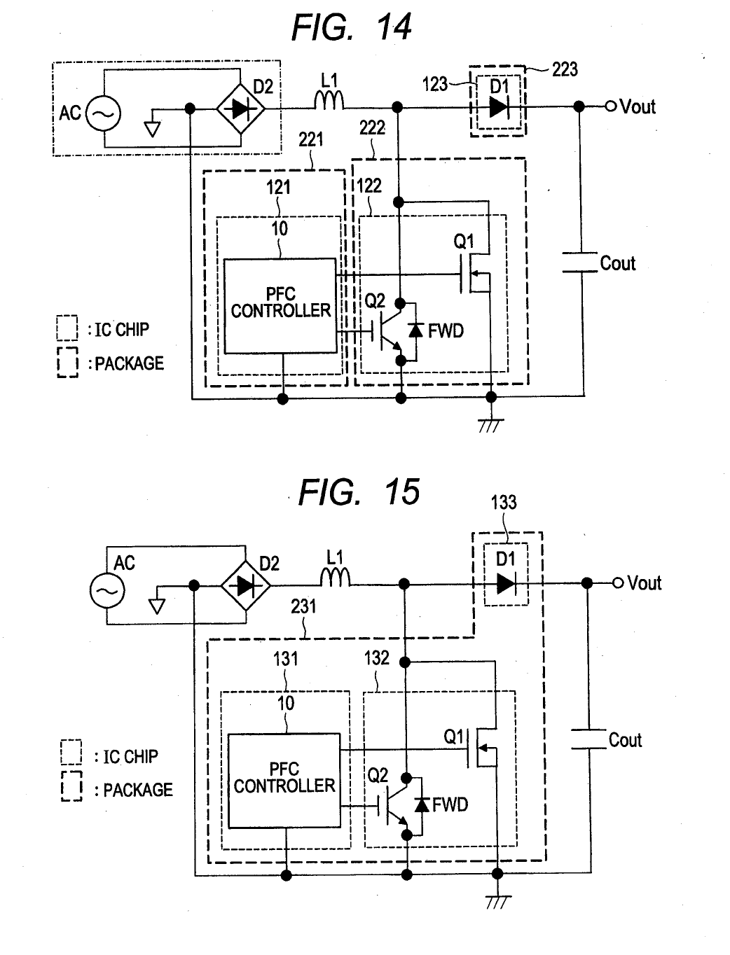

FIG. 14 is a conceptual diagram showing allocation of another packaging of circuits related to the invention.

In the diagram, the PFC controller 10 is mounted on a first IC chip 121, the MOSFET switch Q1 and the IGBT switch Q2 are mounted on a second IC chip 122, and the diode D1 is mounted on a third IC chip 123. The first IC chip 121 is mounted on a first package 221, the second IC chip 122 is mounted on a second package 222, and the third IC chip 123 is mounted on a third package 223.

FIG. 15 is a conceptual diagram showing allocation of another packaging of circuits related to the invention.

In the diagram, the PFC controller 10 is mounted on a first IC chip 131, the MOSFET switch Q1 and the IGBT switch Q2 are mounted on a second IC chip 132, and the diode D1 is mounted on a third IC chip 133. All of the IC chips are mounted on a package 231.

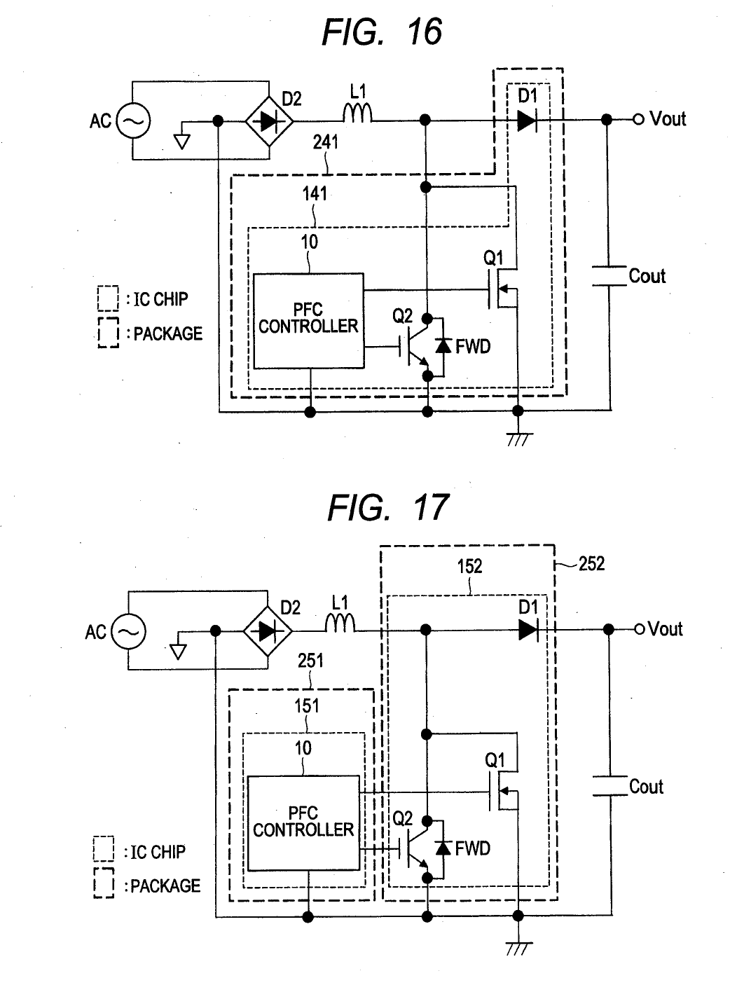

FIG. 16 is a conceptual diagram showing allocation of another packaging of circuits related to the invention.

In the diagram, the PFC controller 10, the MOSFET switch Q1, the IGBT switch Q2, and the diode D1 are mounted on a single IC chip 141. A 1-chip 1-package configuration that the IC chip 141 is mounted on a package 241 is obtained.

FIG. 17 is a conceptual diagram showing allocation of another packaging of circuits related to the invention.

In the diagram, the PFC controller 10 is mounted on a first IC chip 151 and the MOSFET switch Q1, the IGBT switch Q2, and the diode D1 are mounted on a second IC chip 152. The first IC chip 151 is mounted on a first package 251, and the second IC chip 152 is mounted on a second package 251.

By mounting the circuits of the present invention on the IC chips and packages as described above, they can be mounted on an actual device.

Although the invention achieved by the inventors herein has been described concretely above, obviously, the invention is not limited by the foregoing embodiments but can be variously changed without departing from the gist.

### Eighth Embodiment

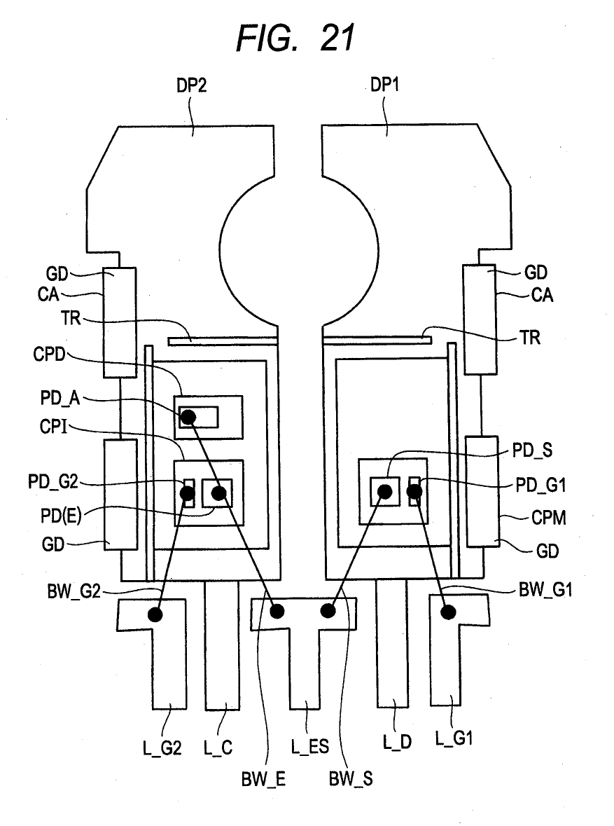

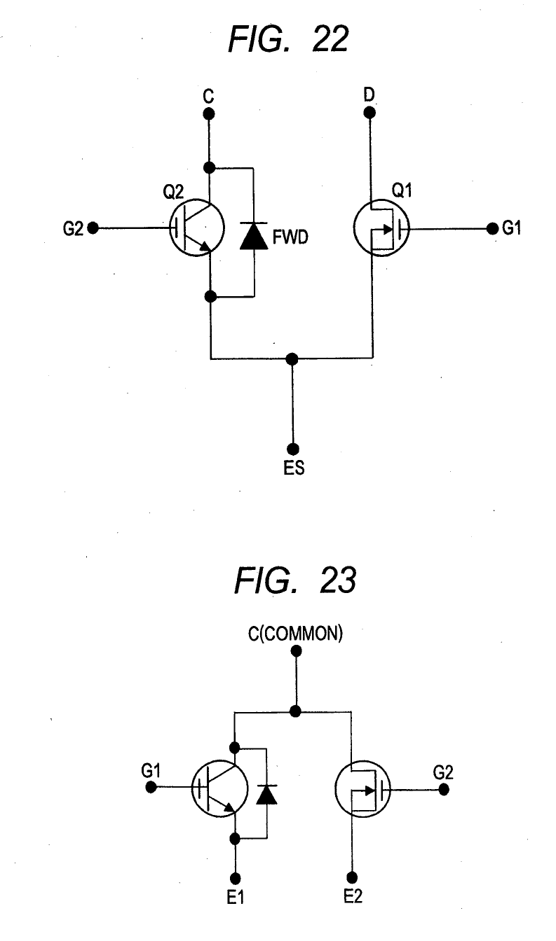

FIGS. 20A to 20C, FIG. 21, and FIG. 22 show the configuration of the case where the MOSFET switch Q1, the IGBT switch Q3, and the free wheel diode FWD are disposed in a single package (semiconductor device). FIGS. 20A, 20B, and 20C show a surface, a side face, and a back face, respectively, of the package. FIG. 21 shows the internal structure of the package. FIG. 22 is an equivalent circuit diagram.

A semiconductor chip CPM on which the MOSFET switch Q1 is formed (hereinbelow, called a MOSFET chip) is mounted on a die pad DP1 formed by a metal plate of copper or the like via a conductive adhesive CA. A semiconductor chip CPI on which the IGBT switch Q2 is formed (hereinbelow, called an IGBT chip) and a semiconductor chip CPD on which the free wheel diode FWD is formed (hereinbelow, called a diode chip) are mounted on a die pad DP2 via the conductive adhesive CA. A gate electrode pad PD_G1 and a source electrode pad PD_S of the MOSFET chip CPM are electrically coupled to a lead L_G1 (first lead for gate) and a lead L_ES (lead for emitter and source) via a bonding wire BW_G1 (first wire for gate) and a bonding wire BW_S (wire for source), respectively. A gate electrode pad PD_G2 and an emitter electrode pad PD(E) of the IGBT chip CPI are electrically coupled to a lead L_G2 (second lead for gate) and the lead L_ES via a bonding wire BW_G2 (second wire for gate) and a bonding wire BW_E (wire for emitter), respectively. An anode electrode PD_A of the diode chip CPD is electrically coupled to the emitter electrode and the lead L_ES of the IGBT chip CPI via the bonding wire BW_E. A drain electrode is formed on the back side of the MOSFET chip CPM and is electrically coupled to a lead L_D (lead for drain). A collector electrode and a cathode electrode are formed on the back side of the IGBT chip and the diode chip, respectively, and are electrically coupled to a lead L_C (lead for collector).

The MOSFET chip CPM, the IGBT chip CPI, and the diode chip CPD are sealed by a sealing member of resin or the like. In the die pads DP1 and DP2, trenches TR for preventing interface debonding from the sealing member are formed. Further, a step GD thinner than the other region is formed in each of the die pads DP1 and DP2. The step GD is also useful to prevent interface debonding from the sealing member. A through hole TH is formed in the sealing member. The through hole TH is used to mount the package on a mounting board by screwing.

In the embodiment, the source electrode PD_S of the MOSFET chip CPM and the emitter electrode PD(E) of the IGBT chip CPI are electrically coupled in the package.

### Ninth Embodiment

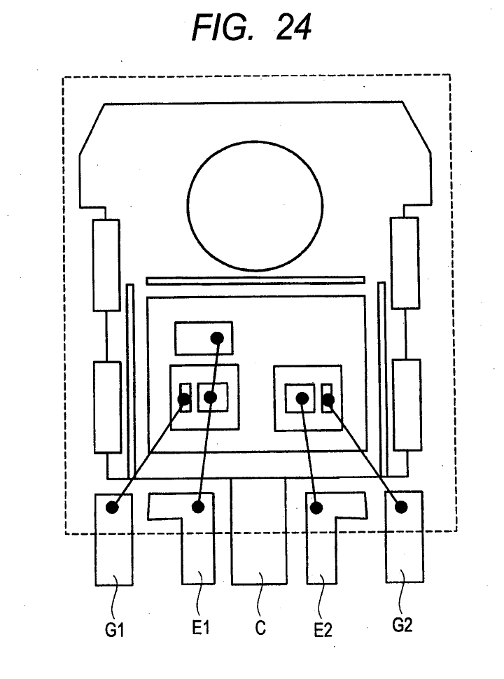

FIGS. 23 and 24 show a ninth embodiment. In the ninth embodiment, different from the eighth embodiment, the drain electrode of the MOSFET chip CPM and the collector electrode of the IGBT chip CPI are electrically coupled in the package. The point different from the eighth embodiment will be described. The other points are similar to those of the eighth embodiment.

On a die pad DP, the MOSFET chip CPM, the IGBT chip CPI, and the diode chip CPI are mounted via the conductive adhesive CA. The gate electrode pad PD_G1 and the source electrode pad PD_S of the MOSFET chip CPM are electrically coupled to the lead L_G1 (first lead for gate) and the lead L_S (lead for source) via the bonding wire BW_G1 (first wire for gate) and the bonding wire BW_S (wire for source), respectively. The gate electrode pad PD_G2 and the emitter electrode pad PD(E) of the IGBT chip CPI are electrically coupled to the lead L_G2 (second lead for gate) and the lead L_ES (lead for emitter and source) via the bonding wire BW_G2 (second wire for gate) and the bonding wire BW_E (wire for emitter), respectively. The anode electrode PD_A of the diode chip CPD is electrically coupled to the emitter electrode and the lead L_E (lead for emitter) of the IGBT chip CPI via the bonding wire BW_E (wire for emitter). A drain electrode, a collector electrode, and a cathode electrode are formed on the back side of the MOSFET chip CPM, the IGBT chip CPI, and the diode chip CPD, respectively, and are electrically coupled to the lead L_CD (lead for collector/drain).

Although the invention achieved by the inventors herein has been concretely described on the basis of the embodiments above, the invention is not limited to the foregoing embodiments. Obviously, the invention can be variously changed without departing from the gist.

1. An electronic device in which an AC full-wave rectifier circuit, an inductor for smoothing, and a diode for rectification are coupled in series and a capacitor for smoothing is grounded between the diode for rectification and an output terminal,
the electronic device comprising:
a control circuit; and
first and second switches for controlling the inductor for smoothing and grounded in parallel,
wherein the control circuit controls each of the first and second switches.

2. The electronic device according to claim 1, further comprising a voltage dividing circuit for dividing voltage of the output terminal,
wherein the control circuit controls the first and second switches by using an output of the voltage dividing circuit.

3. The electronic device according to claim 2, wherein the control circuit internally has a threshold voltage, compares the threshold voltage with an output of the voltage dividing circuit, and switches the first and second switches.

4. The electronic device according to claim 3,
wherein when the output of the voltage dividing circuit is smaller than the threshold voltage, only the first switch is operated, and
wherein when the output of the voltage dividing circuit is larger than the threshold voltage, the first and second switches are operated.

5. The electronic device according to claim 3,
wherein when the output of the voltage dividing circuit is smaller than the threshold voltage, only the first switch is operated, and
wherein when the output of the voltage dividing circuit is larger than the threshold voltage, only the second switch is operated.

6. The electronic device according to claim 1, further comprising a resistor for measurement between the output terminal and the diode for rectification,
wherein the control circuit controls the first and second switches by using a potential difference at both ends of the resistor for measurement.

7. The electronic device according to claim 6, wherein the control circuit has internally a threshold voltage, compares the threshold voltage with the potential difference between both ends of the resistor for measurement, and switches the first and second switches.

8. The electronic device according to claim 7,
wherein when the potential difference between both ends of the resistor for measurement is smaller than the threshold voltage, only the first switch is operated, and
wherein when the potential difference between both ends of the resistor for measurement is larger than the threshold voltage, the first and second switches are operated.

9. The electronic device according to claim 7,
wherein when the potential difference between both ends of the resistor for measurement is smaller than the threshold voltage, only the first switch is operated, and
wherein when the potential difference between both ends of the resistor for measurement is larger than the threshold voltage, only the second switch is operated.

10. The electronic device according to claim 1,
wherein the first switch is grounded via a first resistor for measurement, and the second switch is grounded via a second resistor for measurement, and
wherein the control circuit controls the first and second switches by using an addition voltage obtained by adding a voltage at a connection point between the first resistor for measurement and the first switch and a voltage at a connection point between the second resistor for measurement and the second switch.

11. The electronic device according to claim 10, wherein the control circuit internally has a threshold voltage, compares the threshold voltage with the addition voltage, and switches the first and second switches.

12. The electronic device according to claim 11, wherein when the addition voltage is smaller than the threshold voltage, only the first switch is operated, and
wherein when the addition voltage is larger than the threshold voltage, the first and second switches are operated.

13. The electronic device according to claim 11,
wherein when the addition voltage is smaller than the threshold voltage, only the first switch is operated, and
wherein when the addition voltage is larger than the threshold voltage, only the second switch is operated.

14. The electronic device according to claim 1,
wherein the control circuit includes a reference voltage circuit for generating a threshold voltage, and
wherein a voltage is divided by a voltage dividing circuit on the outside of the control circuit, and the control circuit uses an output of the voltage dividing circuit as a threshold.

15. The electronic device according to claim 1,
wherein the control circuit includes a reference voltage circuit for generating a threshold voltage,
wherein an output of the reference voltage circuit is divided by first and second voltage dividing circuits on the outside of the control circuit, and
wherein the control circuit uses an output of the first voltage dividing circuit as a first voltage threshold and uses an output of the second voltage dividing circuit as a second voltage threshold.

16. The electronic device according to claim 15,
wherein the control circuit has an AC detection circuit and a change-over switch,
wherein the change-over switch can switch the first and second voltage thresholds, and
wherein the AC detection circuit switches the change-over switch using an output of the AC full-wave rectifier circuit as a reference.

17. An electronic device in which an AC full-wave rectifier circuit, a transformer, and a diode for rectification are coupled in series, and an inductor for smoothing is grounded between the diode for rectification and an output terminal,
the electronic device comprising:
first and second switches for controlling the inductor for smoothing and grounded in parallel; and
a control circuit for performing zero current detection by a secondary winding of the transformer and controlling each of the first and second switches.

18. The electronic device according to claim 1, wherein the first switch is a MOSFET switch, and the second switch is an IGBT switch.

19. The electronic device according to claim 1, wherein current capacity of the first switch is smaller than that of the second switch.

20. A semiconductor device comprising:
first and second die pads made of metal;
a first semiconductor chip mounted on the first die pad and on which a MOSFET is formed;
a second semiconductor chip mounted on the second die pad and on which an IGBT is formed; and
a sealing member covering the first and second semiconductor chips,
wherein the first semiconductor chip has a source electrode, a gate electrode, and a drain electrode of the MOSFET,
wherein the second semiconductor chip has an emitter electrode, a base electrode, and a collector electrode of the IGBT, and
wherein the source electrode of the first semiconductor chip and the emitter electrode of the second semiconductor chip are electrically coupled.

21. The semiconductor device according to claim 20, further comprising:
a first lead for gate electrically coupled to the gate electrode of the first semiconductor chip;
a lead for drain electrically coupled to the drain electrode of the first semiconductor chip;
a second lead for gate electrically coupled to the base electrode of the second semiconductor chip;
a lead for collector electrically coupled to the collector electrode of the second semiconductor chip; and
a lead for emitter/source electrically coupled to the source electrode of the first semiconductor chip and the emitter electrode of the second semiconductor chip.

22. The semiconductor device according to claim 20, wherein a diode is electrically coupled between the emitter and the collector of the IGBT.

23. The semiconductor device according to claim 22, further comprising a third semiconductor chip on which the diode is formed and which is mounted on the second die pad.

24. A semiconductor device comprising:
a die pad made of metal;
a first semiconductor chip on which a MOSFET is formed and a second semiconductor chip on which an IGBT is formed, the first and second semiconductor chips being mounted on the die pad; and
a sealing member covering the first and second semiconductor chips,
wherein the first semiconductor chip has a source electrode, a gate electrode, and a drain electrode of the MOSFET,
wherein the second semiconductor chip has an emitter electrode, a base electrode, and a collector electrode of the IGBT, and
wherein the drain electrode of the first semiconductor chip and the collector electrode of the second semiconductor chip are electrically coupled.

25. The semiconductor device according to claim 24, further comprising:
a first lead for gate electrically coupled to the gate electrode of the first semiconductor chip;
a lead for source electrically coupled to the source electrode of the first semiconductor chip;
a lead for emitter electrically coupled to the emitter electrode of the second semiconductor chip; and
a lead for drain/collector electrically coupled to the drain electrode of the first semiconductor chip and the collector electrode of the second semiconductor chip.

26. The semiconductor device according to claim 24, wherein a diode is electrically coupled between the emitter electrode and the collector electrode of the IGBT.

27. The semiconductor device according to claim 26, further comprising a third semiconductor chip on which the diode is formed and which is mounted on the die pad.
